(19) United States
(12) Patent Application Publication
(10) Pub. No.: US 2018/0373069 A1
(43) Pub. Date: Dec. 27, 2018

(54) COG PANEL CONVENIENT FOR TESTING

(71) Applicant: WUHAN CHINA STAR OPTOELECTRONICS TECHNOLOGY CO., LTD., Wuhan, Hubei (CN)

(72) Inventors: Zhenzhou Xing, Wuhan, Hubei (CN); Qingcheng Zuo, Wuhan, Hubei (CN)

(21) Appl. No.: 15/566,092

(22) PCT Filed: Jul. 6, 2017
(86) PCT No.: PCT/CN2017/092118

§ 371 Date: Oct. 12, 2017

(30) Foreign Application Priority Data
Jun. 27, 2017 (CN) 201710502183.0

(51) Int. Cl. G02F 1/13; G02F 1/1345; H01L 23/498; G01R 31/28

(52) U.S. Cl. CPC G02F 1/1309; G02F 1/13452; G01R 31/2884; H01L 23/49838; H01L 23/49811

(57) ABSTRACT

The present disclosure provides a COG panel convenient for testing that includes a glass panel and a driver IC provided at a back of a bonding end of the glass panel, wherein the glass panel includes a connecting end fixed at the bonding end; the connecting end is provided with a plurality of wires connecting to the driver IC, respectively and being parallel with each other, and testing terminals provided at a free end of each wire; and the connecting end extends along a length direction of the bonding end, and is closer to a free end of the bonding end with respect to the driver IC. The bonding end of the COG panel of the present disclosure is provided with a connecting end convenient for testing which may simplify testing procedure and improve testing efficiency.

### TECHNICAL FIELD

The present disclosure relates to the technical field of liquid crystal panel testing, particularly, to a COG panel convenient for testing.

### RELATED ART

Currently, shipments of various manufacturers of TFT LCD (thin film transistor-liquid crystal display) liquid crystal panel include the following forms: Open Cell shipment; COG (chip on glass, i.e., the chip is carried on a glass panel) shipment; FOG (film on glass, i.e., a flexible circuit board is carried on a glass panel) shipment; and MOD (module, i.e., a backlight module) shipment. The Open Cell refers to only including a Cell (a glass panel) without bonding a driver IC and an FPC (flexible circuit board), and not having a backlight; the COG refers to only bonding a driver IC on the Cell without an FPC and a backlight; the FOG refers to bonding a driver IC and an FPC on the Cell without a backlight; and the MOD refers to including the a driver IC, an FPC and a backlight.

However, the TFT LCD liquid crystal panel manufacturers need to conduct tests on display effect and other performances before shipment in whatever form, and goods will not be shipped to the customer only when all of them comply with quality standards and customer requirements. The current shipment forms mainly lie in Cell shipment and MOD shipment. There is no certain testing method for COG shipment to guarantee that the display effect and other performances of the goods for shipment can all comply with corresponding quality standards and customer requirement.

### SUMMARY

In view of the defects existing in the prior art, the present disclosure provides a COG panel convenient for testing which may simplify testing procedure and improve testing efficiency.

In order to achieve the above purposes, the present disclosure adopts the following technical solutions:

a COG panel convenient for testing includes a glass panel and a driver IC provided at a back of a bonding end of the glass panel, wherein the glass panel includes a connecting end fixed at the bonding end; the connecting end is provided with a plurality of wires connecting to the driver IC, respectively and being parallel with each other, and testing terminals provided at a free end of each wire; and the connecting end extends along a length direction of the bonding end, and is closer to a free end of the bonding end with respect to the driver IC.

As one embodiment thereof, the testing terminals of the connecting end are arranged to be linear terminal groups with plural columns being parallel with each other, each column of linear terminal group includes a plurality of testing terminals and the linear terminal group extends in the same direction with the length direction of the bonding end.

As one embodiment thereof, at least one testing terminal in another column of linear terminal group is interposed between every two adjacent testing terminals in one column of linear terminal group close to the free end of the bonding end.

As one embodiment thereof, the number of the linear terminal groups is 2.

As one embodiment thereof, one testing terminal in another linear terminal group is interposed between every two adjacent testing terminals in the linear terminal group close to the free end of the bonding end.

As one embodiment thereof, the testing terminals in the same column of testing terminals have the same shape.

As one embodiment thereof, the testing terminal in the linear terminal group close to the driver IC is a triangle, and the triangular testing terminal has one side facing a side where the driver IC is located, and two other sides facing the linear terminal group close to the free end of the bonding end; in the linear terminal group close to the free end of the bonding end, two sloping sides enclosing an angle portion are provided on each testing terminal facing a side where the driver IC is located.

As one embodiment thereof, the testing terminals of each column of linear terminal group are all in a triangular shape.

Or, in the linear terminal group close to the free end of the bonding end, each testing terminal is in a rhombus shape.

As one embodiment thereof, the connecting end includes a substrate layer on which the wires and the testing terminals are integrated and on which a rip wire being perpendicular to the wires and dividing the wires into two portions is provided.

The bonding end of the COG panel of the present disclosure is provided with a connecting end convenient for testing which may simplify testing procedure and improve testing efficiency. Furthermore, a testing structure may occupy the least space by arranging the testing terminals in a specific arrangement manner, which is more convenient for testing.

### BRIEF DESCRIPTION OF THE DRAWINGS

FIG. 1 is a structure diagram of a COG panel of Embodiment 1 of the present disclosure;

FIG. 2 is a partial enlarged view of a bonding end of the COG panel of Embodiment 1 of the present disclosure;

FIG. 3 is a partial enlarged view of another structure of the bonding end of the COG panel of Embodiment 1 of the present disclosure;

FIG. 4 is a structure diagram of a COG panel of Embodiment 2 of the present disclosure; and

FIG. 5 is a partial enlarged view of the bonding end of the COG panel of Embodiment 2 of the present disclosure.

### DETAILED DESCRIPTION OF EXEMPLARY EMBODIMENTS

In order for the purpose, technical solutions and advantages of the present disclosure to be clearer and better understood, the present disclosure will be further explained below in conjunction with the figures using exemplary embodiments. It should be understood that detailed embodiments described here are only used to explain the present disclosure, but not used to define the present disclosure.

### Embodiment 1

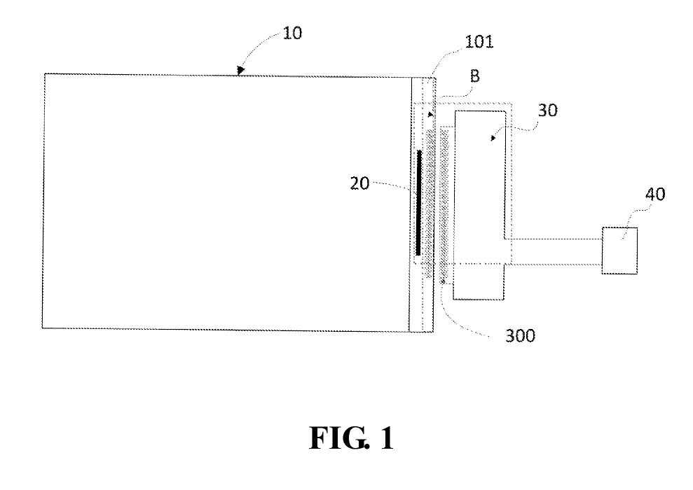

Referring to FIG. 1, a COG panel convenient for testing of the present embodiment includes a glass panel 10 and a driver IC 20 provided at a back of a bonding end of the glass panel 10, wherein the glass panel 10 includes a connecting end B fixed at the bonding end; the connecting end B is provided with a plurality of wires L connecting to the driver IC 20, respectively and being parallel with each other, and testing terminals 100 provided at a free end of each wire L; and the connecting end B extends along a length direction of the bonding end, and is closer to a free end of the bonding end with respect to the driver IC 20. The COG panel is not provided with an FPC. An FPC 30 connected with a main control chip 40 and the connecting end B are only needed to be conducted through a connecting finger 300 on the FPC 30 after the completion of the shipment. When a test is conducted before the shipment, performances of products such as a display effect can be tested only by inputting testing signals through the connecting end B.

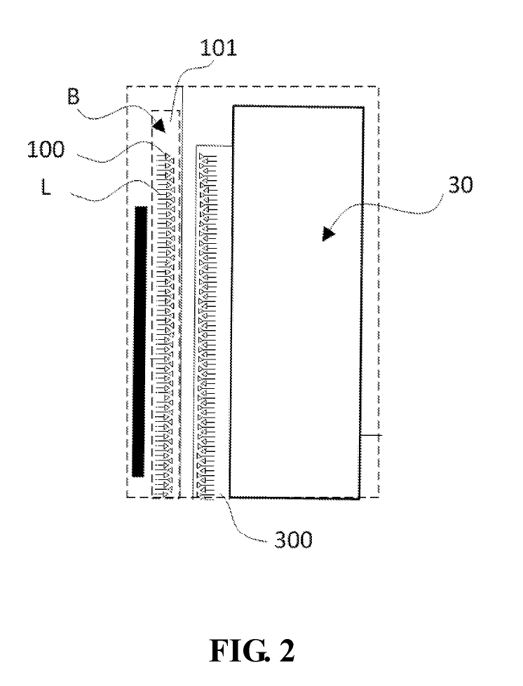

As illustrated in FIG. 2, the testing terminals 100 of the connecting end B are arranged to be linear terminal groups with plural columns being parallel with each other, and each column of linear terminal group includes a plurality of testing terminals 100 and the linear terminal group extends in the same direction with the length direction of the bonding end. A protruding position of the testing terminal 100 and a length of corresponding wire L can be reasonably designed by dividing the testing terminals 100 into a plurality of groups of linear terminal groups spaced apart from each other, which can reduce an entire area occupied by the connecting end B on one hand, and on the other end, facilitate alignment of the terminals of the connecting finger 300 of the FPB 30 or an external testing circuit with the testing terminals 100 so as to improve testing efficiency.

At least one testing terminal 100 in another column of linear terminal group is interposed between every two adjacent testing terminals 100 in one column of linear terminal group close to the free end of the bonding end. The number of the linear terminal groups selected in the present embodiment is 2, and the two groups of linear terminal groups are arranged in a left-and-right manner (the orientation as illustrated in FIG. 2) with each testing terminal 100 extending to be connected with the driver IC 20 through a corresponding wire L all of which are parallel with each other. One testing terminal 100 in another linear terminal group is interposed between every two adjacent testing terminals 100 in the linear terminal group close to the free end of the bonding end.

In order to facilitate wiring and save space as much as possible, it is preferably that each testing terminal 100 in the same column of testing terminals 100 is made to have the same shape. Here, the testing terminal 100 in the linear terminal group close to the driver IC 20 is a triangle, and the triangular testing terminal 100 has one side facing a side where the driver IC 20 is located, and two other sides facing the linear terminal group close to the free end of the bonding end; meanwhile, in the linear terminal group close to the free end of the bonding end, two sloping sides enclosing an angle portion are provided on each testing terminal 100 facing a side where the driver IC 20 is located. After two columns of linear terminal groups are arranged, two triangular testing terminals 100 on the left enclose an arrangement space for receiving the testing terminal 100 on the right, and an angle portion of the testing terminal 100 on the right is embedded into the arrangement space, and has two sloping sides provided opposite to, preferably in parallel with, corresponding sides of the two triangles on the left, so as to avoid unnecessarily gaps to a largest extent.

In the present embodiment, the testing terminals 100 of each column of linear terminal group are all further provided to be a structure of an isosceles triangle shape, that is, a central portion of a bottom side of the isosceles triangle of each testing terminal 100 in the linear terminal group close to the driver IC 20 is connected with respective wires L with a top angle facing another column of linear terminal group, and a vertex angle of the isosceles triangle of each testing terminal 100 in another column of linear terminal group is connected with respective wires L so as to make two sides of the vertex angle thereof face two testing terminals 100 of the adjacent linear terminal group, respectively. At last, every two adjacent testing terminals 100 in the linear terminal group close to the driver IC 20 enclose one end of one testing terminal 100 in the adjacent linear terminal group, and the three testing terminals 100 enclose a space in an isosceles trapezoid shape, so as to make the structures of the linear terminal groups be more compact. Correspondingly, in order to facilitate connection with the connecting end B of the COG panel, the terminals of the connecting finger 300 of the FPC 30 or the external testing circuit may also be designed to be a similar structure, that is, also having wires and a plurality of groups of terminals connected with respective wires, respectively, and the plurality of groups of terminals are arranged to match with the testing terminals 100 of the connecting end B, that is, if the connecting end B has a protruding part of the testing terminal, terminals of the connecting finger 300 (or terminals of the external testing circuit) are in a retracting state, and if the connecting end B has a retracting part of the testing terminal, the terminals of the connecting finger 300 (or terminals of the external testing circuit) are in a protruding state.

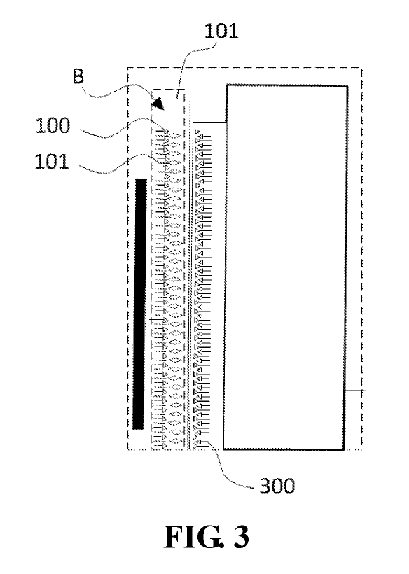

As illustrated in FIG. 3, in the linear terminal group close to the free end of the bonding end, each testing terminal 100 may also be in a rhombus shape, so that the testing terminal 100 in the linear terminal group is more protruded and can be aligned with the terminal of connecting finger 300 of the FPC 30 or external testing circuit more conveniently, rapidly and accurately.

### Embodiment 2

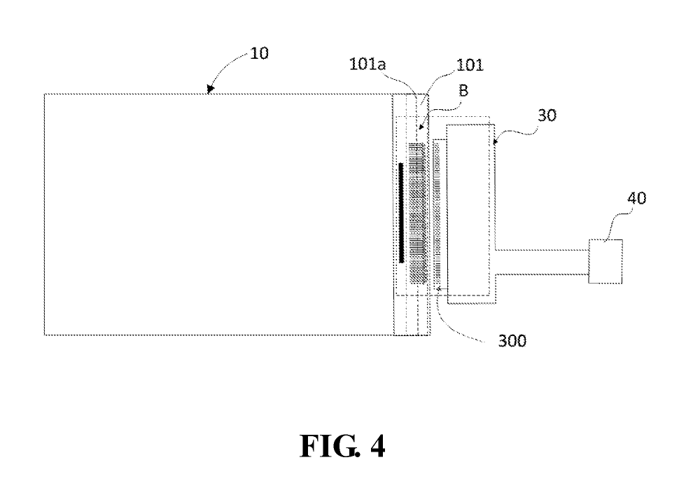

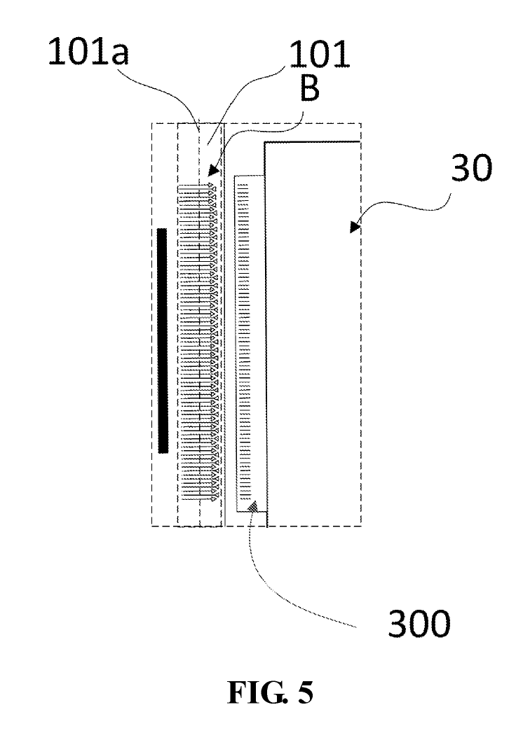

As illustrated in FIGS. 4 and 5, different from Embodiment 1, the connecting end B of the present embodiment further includes, on the basis of the Embodiment 1, a substrate layer 101 on which the wires and the testing terminals 100 are integrated and on which a rip wire 101a being perpendicular to the wires and dividing the wires into two portions is provided. After the completion of the test, it only needs to be torn along the rip wire 101a, an end where the substrate layer 101 having the testing terminals 100 is located can be torn off, and the testing terminals 100 are also torn off. From the view of the appearance, the COG panel is no different from a normal one.

The bonding end of the COG panel of the present disclosure is provided with a connecting end convenient for testing which may simplify testing procedure and improve testing efficiency. Furthermore, a testing structure may occupy the least space by arranging the testing terminals in a specific arrangement manner, which is more convenient for testing.

The above statements are only the specific embodiments of the present application, it should be pointed out that, to those ordinary skilled in the art, several improvements and polish can be made without deviating away from the principle of the present application, those improvements and polish should also be considered as the protection scope of the present application.

What is claimed is:

1. A chip on glass (COG) panel convenient for testing, comprising:
a glass panel; and
a driver IC provided at a back of a bonding end of the glass panel,
wherein the glass panel comprises a connecting end fixed at the bonding end; the connecting end is provided with a plurality of wires connecting to the driver IC, respectively and being parallel with each other, and testing terminals provided at a free end of each wire; and the connecting end extends along a length direction of the bonding end, and is closer to a free end of the bonding end with respect to the driver IC.

2. The COG panel convenient for testing according to claim 1, wherein the connecting end comprises a substrate layer on which the wires and the testing terminals are integrated and on which a rip wire being perpendicular to the wires and dividing the wires into two portions is provided.

3. The COG panel convenient for testing according to claim 1, wherein the testing terminals of the connecting end are arranged to be linear terminal groups with plural columns being parallel with each other, each column of linear terminal group comprises a plurality of testing terminals and the linear terminal group extends in the same direction with the length direction of the bonding end.

4. The COG panel convenient for testing according to claim 3, wherein the connecting end comprises a substrate layer on which the wires and the testing terminals are integrated and on which a rip wire being perpendicular to the wires and dividing the wires into two portions is provided.

5. The COG panel convenient for testing according to claim 3, wherein at least one testing terminal in another column of linear terminal group is interposed between every two adjacent testing terminals in one column of linear terminal group close to the free end of the bonding end.

6. The COG panel convenient for testing according to claim 5, wherein the connecting end comprises a substrate layer on which the wires and the testing terminals are integrated and on which a rip wire being perpendicular to the wires and dividing the wires into two portions is provided.

7. The COG panel convenient for testing according to claim 3, wherein the number of the linear terminal groups is 2.

8. The COG panel convenient for testing according to claim 7, wherein the connecting end comprises a substrate layer on which the wires and the testing terminals are integrated and on which a rip wire being perpendicular to the wires and dividing the wires into two portions is provided.

9. The COG panel convenient for testing according to claim 7, wherein one testing terminal in another linear terminal group is interposed between every two adjacent testing terminals in the linear terminal group close to the free end of the bonding end.

10. The COG panel convenient for testing according to claim 9, wherein the connecting end comprises a substrate layer on which the wires and the testing terminals are integrated and on which a rip wire being perpendicular to the wires and dividing the wires into two portions is provided.

11. The COG panel convenient for testing according to claim 9, wherein the testing terminals in the same column of testing terminals have the same shape.

12. The COG panel convenient for testing according to claim 11, wherein the connecting end comprises a substrate layer on which the wires and the testing terminals are integrated and on which a rip wire being perpendicular to the wires and dividing the wires into two portions is provided.

13. The COG panel convenient for testing according to claim 11, wherein the testing terminal in the linear terminal group close to the driver IC has a shape of triangle, and the triangular testing terminal has one side facing a side where the driver IC is located, and two other sides facing the linear terminal group close to the free end of the bonding end; and in the linear terminal group close to the free end of the bonding end, two sloping sides enclosing an angle portion are provided on each testing terminal facing a side where the driver IC is located.

14. The COG panel convenient for testing according to claim 13, wherein the connecting end comprises a substrate layer on which the wires and the testing terminals are integrated and on which a rip wire being perpendicular to the wires and dividing the wires into two portions is provided.

15. The COG panel convenient for testing according to claim 13, wherein the testing terminals of each column of linear terminal group are all in a triangular shape.

16. The COG panel convenient for testing according to claim 15, wherein the connecting end comprises a substrate layer on which the wires and the testing terminals are integrated and on which a rip wire being perpendicular to the wires and dividing the wires into two portions is provided.

17. The COG panel convenient for testing according to claim 13, wherein in the linear terminal group close to the free end of the bonding end, each testing terminal is in a rhombus shape.

18. The COG panel convenient for testing according to claim 17, wherein the connecting end comprises a substrate layer on which the wires and the testing terminals are integrated and on which a rip wire being perpendicular to the wires and dividing the wires into two portions is provided.

19. A COG panel convenient for testing, comprising:
a glass panel; and
a driver IC provided at a back of a bonding end of the glass panel,
wherein the glass panel comprises a connecting end fixed at the bonding end; the connecting end is provided with a plurality of wires connecting to the driver IC, respectively and being parallel with each other, and testing terminals provided at a free end of each wire, and the connecting end comprises a substrate layer on which the wires and the testing terminals are integrated and on which a rip wire being perpendicular to the wires and dividing the wires into two portions is provided; the connecting end extends along a length direction of the bonding end, and is closer to a free end of the bonding end with respect to the driver IC; and the testing terminals of the connecting end are arranged to be linear terminal groups with plural columns being parallel with each other, each column of linear terminal group comprises a plurality of testing terminals, the linear terminal group extends in the same direction with the length direction of the bonding end, and the testing terminals of each column of linear terminal group are all in a triangular shape.
